(19) United States
(12) Patent Application Publication
(10) Pub. No.: US 2023/0052492 A1
(43) Pub. Date: Feb. 16, 2023

(54) DISPLAY APPARATUS

(71) Applicant: SONY SEMICONDUCTOR SOLUTIONS CORPORATION, KANAGAWA (JP)

(72) Inventor: NAOKI OGAWA, KANAGAWA (JP)

(21) Appl. No.: 17/796,384

(22) PCT Filed: Jan. 26, 2021
(86) PCT No.: PCT/JP2021/002637

§ 371 Date: Jul. 29, 2022

(30) Foreign Application Priority Data
Feb. 7, 2020 (JP) 2020-019371

(51) Int. Cl. H01L 33/50; H01L 33/62; H01L 27/15

(52) U.S. Cl. CPC H01L 33/504; H01L 33/62; H01L 27/156

(57) ABSTRACT

A display apparatus includes: a light-emitting device layer provided to extend over a plurality of pixels arranged two-dimensionally; a phosphor layer separated by a partition wall for each of the pixels; and a bonding structure sandwiched between the light-emitting device layer and the phosphor layer, and in which a first oxidation film, a bonding oxidation film, and a second oxidation film are stacked in order from the light-emitting device layer side.

### TECHNICAL FIELD

The present disclosure relates to a display apparatus.

### BACKGROUND ART

A light-emitting device (Light Emitting Diode: LED) that converts an electric energy into a light energy attracts an attention as a light source of, for example, a display apparatus owing to its fast response speed and low power consumption (e.g., Patent Literature 1).

It is possible to manufacture the display apparatus that uses the light-emitting device by, for example, bonding a substrate in which light-emitting devices are so provided as to extend over a plurality of pixels and a substrate in which a drive circuit that drives the light-emitting devices is provided, and then providing a phosphor, a color filter, or the like for each pixel on the light-emitting devices.

### CITATION LIST

### Patent Literature

Patent Literature 1: Japanese Unexamined Patent Application Publication No. 2018-182282

### SUMMARY OF THE INVENTION

In such a display apparatus, it is desired to suppress a variation in luminance or tone for each pixel. Accordingly, it is desired to improve a uniformity of each pixel in the display apparatus by forming a structure around the pixels of the display apparatus with higher accuracy.

Therefore, it is desirable to provide a display apparatus that makes it possible to further increase a uniformity of each pixel.

A display apparatus according to one embodiment of the present disclosure includes: a light-emitting device layer provided to extend over a plurality of pixels arranged two-dimensionally; a phosphor layer separated by a partition wall for each of the pixels; and a bonding structure sandwiched between the light-emitting device layer and the phosphor layer, and in which a first oxidation film, a bonding oxidation film, and a second oxidation film are stacked in order from the light-emitting device layer side.

According to the display apparatus of one embodiment of the present disclosure, the bonding structure in which the first oxidation film, the bonding oxidation film, and the second oxidation film are stacked in order from the light-emitting device layer side is sandwiched between the light-emitting device layer provided to extend over the plurality of pixels arranged two-dimensionally and the phosphor layer separated by the partition wall for each of the pixels. Thus, for example, it is possible for the display apparatus to further increase a uniformity of a height of the partition wall that separates the phosphor layer for each of the pixels.

### BRIEF DESCRIPTION OF THE DRAWINGS

FIG. 1 is a vertical cross-sectional diagram illustrating an example of a configuration of a display apparatus according to an embodiment of the present disclosure.

FIG. 2A is a vertical cross-sectional diagram illustrating a step of bonding a drive substrate and a light-emitting device layer.

FIG. 2B is a vertical cross-sectional diagram illustrating a step of bonding the drive substrate and the light-emitting device layer.

FIG. 2C is a vertical cross-sectional diagram illustrating a step of bonding the drive substrate and the light-emitting device layer.

FIG. 3A is a vertical cross-sectional diagram illustrating a step of stacking a counter substrate and a phosphor layer.

FIG. 3B is a vertical cross-sectional diagram illustrating a step of stacking the counter substrate and the phosphor layer.

FIG. 3C is a vertical cross-sectional diagram illustrating a step of stacking the counter substrate and the phosphor layer.

FIG. 3D is a vertical cross-sectional diagram illustrating a step of stacking the counter substrate and the phosphor layer.

FIG. 4A is a vertical cross-sectional diagram illustrating a step of bonding the light-emitting device layer and the phosphor layer.

FIG. 4B is a vertical cross-sectional diagram illustrating a step of bonding the light-emitting device layer and the phosphor layer.

FIG. 5 is a vertical cross-sectional diagram illustrating a configuration of a display apparatus according to a first modification example.

FIG. 6 is a vertical cross-sectional diagram illustrating a configuration of a display apparatus according to a second modification example.

FIG. 7 is a schematic diagram illustrating an appearance of a television apparatus to which the display apparatus according to an embodiment of the present disclosure is applied.

### MODES FOR CARRYING OUT THE INVENTION

Hereinafter, embodiments of the present disclosure will be described in detail with reference to the drawings. The embodiments to be described below are concrete examples of the present disclosure, and a technique according to the present disclosure is not limited to the following embodiments. In addition, the arrangement, the dimensions, the dimensional ratios, and the like of the respective components of the present disclosure are not limited to the embodiments illustrated in the respective drawings.

The description will be made in the following order.
1. Configuration of Display Apparatus
2. Method of Manufacturing Display Apparatus
3. Modification Examples
4. Application Example

### 1. CONFIGURATION OF DISPLAY APPARATUS

First, referring to FIG. 1, a configuration of a display apparatus according to an embodiment of the present disclosure will be described. FIG. 1 is a vertical cross-sectional diagram illustrating an example of a configuration of a display apparatus 1 according to the present embodiment.

As illustrated in FIG. 1, the display apparatus 1 according to the present embodiment includes, for example, a light-emitting device layer 110, a phosphor layer 120, a partition wall 121, a bonding structure 130, a counter substrate 140, a drive substrate 150, and a connection part 160. The display apparatus 1 is a display apparatus in which a face, of the counter substrate 140, that is on an opposite side of a face provided with the phosphor layer 120 serves as an image display face. The image display face of the display apparatus 1 is provided with a plurality of pixels arranged two-dimensionally.

The light-emitting device layer 110 is a layer that includes light-emitting devices that spontaneously emit light by application of a voltage. The light-emitting device layer 110 is so provided as to extend over the plurality of pixels arranged two-dimensionally, for example.

The light-emitting device layer 110 may emit light of the same wavelength band, such as UV (UtraViolet) light or white light, over the plurality of pixels, or emit pieces of light of wavelength bands corresponding to respective colors, such as blue, green, or red, for the respective pixels.

The light-emitting device layer 110 may be, for example, a LED panel in which a plurality of light-emitting diodes (Light Emitting Diode: LED) is arranged in a matrix on a substrate.

The light-emitting diode (LED) includes, for example, a structure in which a first electrode, a first conductive-type layer, an active layer, a second conductive-type layer, and a second electrode are stacked in order. In the light-emitting diode (LED), electrons are injected from the first conductive-type layer to the active layer and holes are injected from the second conductive-type layer to the active layer, in response to application of a voltage between the first electrode and the second electrode. The injected electrons and holes combine with each other at the active layer, thereby making it possible to emit light corresponding to a size of a band gap of the active layer.

The first conductive-type layer may be configured by a compound semiconductor of a group III-V element such as an InGaN-based compound semiconductor or an AlGaInP-based compound semiconductor into which a first conductive-type (e.g., n-type) impurity is introduced. The active layer may be configured by a compound semiconductor of a Group III-V element such as an InGaN-based compound semiconductor or an AlGaInP-based compound semiconductor having a smaller band gap than the first conductive-type layer and the second conductive-type layer. It should be noted that either the first conductive-type (e.g., n-type) impurity or the second conductive-type (e.g., p-type) impurity may be introduced into the active layer. The second conductive-type layer may be configured by a compound semiconductor of a Group III-V element such as an InGaN-based compound semiconductor or an AlGaInP-based compound semiconductor into which the second conductive-type (e.g., p-type) impurity is introduced. The first electrode and the second electrode may include a metal material such as Ag (silver), for example.

However, the light-emitting devices included in the light-emitting device layer 110 are not limited to the light-emitting diodes (LED) described above. The light-emitting device included in the light-emitting device layer 110 may be, for example, an organic EL device (Organic Light Emitting Diode: OLED).

The phosphor layer 120 is a layer that includes two or more kinds of light converting substances that convert a color of light emitted from the light-emitting device layer 110. The phosphor layer 120 is provided via a bonding structure 130 on a face, of the light-emitting device layer 110, that is on an opposite side of a face to which the drive substrate 150 is bonded, for example. The phosphor layer 120 includes two or more kinds of light converting substances, and may emit light of three primary colors of red (R), green (G), or blue (B) by converting blue light into each of red light and green light, for example. In such a case, it is possible for the phosphor layer 120 to allow a color image to be displayed on the display apparatus 1.

In addition, the phosphor layer 120 is provided with a partition wall 121 that separates the phosphor layer 120 for each of the pixels, in order to prevent mixing of light converting substances between the pixels. The partition wall 121 may be configured by any material, as long as the material is a material used in a semiconducting process. However, in order to further suppress color mixing between the pixels, the partition wall 121 may include a material having a light shielding property (or not transparent). Further, in order to suppress an influence on an image signal in the light-emitting device layer 110 or the drive substrate 150, the partition wall 121 may include a material having an insulating property.

In a region defined by the partition wall 121, the light converting substance that converts the color of the light emitted from the light-emitting device layer 110 into red (R), green (G), or blue (B) is provided for each of the pixels, for example. The light converting substance may be, for example, a phosphor that makes it possible to emit a fluorescence of red light, green light, or blue light. As such a phosphor, it is possible to use an inorganic fluorescence material, an organic fluorescence material, or quantum dots.

The bonding structure 130 is a stack structure that bonds the light-emitting device layer 110 and the phosphor layer 120 to each other, and is sandwiched between the light-emitting device layer 110 and the phosphor layer 120. Specifically, the bonding structure 130 is provided in a structure in which a first oxidation film 131, a bonding oxidation film 133, and a second oxidation film 132 are sequentially stacked from the light-emitting device layer 110 side.

The first oxidation film 131 and the second oxidation film 132 are layers that supply oxygen atoms to the later-described bonding oxidation film 133 through diffusion. The first oxidation film 131 and the second oxidation film 132 may be configured by an inorganic oxide having a light transmitting property. For example, the first oxidation film 131 and the second oxidation film 132 may be configured by SiO₂ (silicon oxide).

The bonding oxidation film 133 is a film configured by bonding a precursor film provided on each of the light-emitting device layer 110 and the phosphor layer 120 by atomic diffusion bonding and then oxidizing the precursor film with the oxygen atoms diffused from the first oxidation film 131 and the second oxidation film 132. The atomic diffusion bonding is a method of bonding thin films to each other, by attaching thin films formed in an ultra-high vacuum to each other under a vacuum at room temperature and diffusing atoms between the attached thin films. The display apparatus 1 according to the present embodiment makes it possible to bond the light-emitting device layer 110 and the phosphor layer 120 to each other by using the atomic diffusion bonding.

The bonding oxidation film 133 may be configured by an oxide of a metal or a metalloid having a light transmitting property so as not to attenuate the light emitted from the light-emitting device layer 110. Specifically, the bonding oxidation film 133 may be configured by an oxide of Sc, Y, Ti, V, Cr, Fe, Co, Ni, Pd, Cu, Ag, Sg, Mg, Sr, Zn, Zr, Al, or Si, or may be configured by an oxide of an alloy thereof. More specifically, the bonding oxidation film 133 may be configured by an oxide of Ti or Al.

Specifically, it is possible to form the bonding oxidation film 133 by, for example, the following process to bond the light-emitting device layer 110 and the phosphor layer 120 to each other.

First, an unoxidized precursor film of a metal or a metalloid which eventually structures the bonding oxidation film 133 at a later stage is formed on each of mutually opposing faces of the light-emitting device layer 110 and the phosphor layer 120. Next, a precursor film provided on the light-emitting device layer 110 side and a precursor film provided on the phosphor layer 120 side are attached to each other, and atomic diffusion is generated between the attached precursor films to bond the precursor films to each other. Subsequently, a heat process of about 100° C. or less is used to diffuse the oxygen atoms from the first oxidation film 131 and the second oxidation film 132 into the precursor films to oxidize the precursor films by the oxygen atoms. As a result, the precursor films that bond the light-emitting device layer 110 and the phosphor layer 120 to each other become the bonding oxidation film 133 having the light transmitting property.

By using the atomic diffusion bonding, it is possible for the bonding oxidation film 133 to bond the light-emitting device layer 110 and the phosphor layer 120 with an extremely thin films of about several nanometers. Further, the atomic diffusion bonding allows for the bonding at a room temperature, making it possible for the bonding oxidation film 133 to bond the light-emitting device layer 110 and the phosphor layer 120 even in a case where an organic fluorescence material, quantum dots, or the like having low heat resistance is used as the light converting substance.

In the display apparatus 1 according to the present embodiment, the light-emitting device layer 110 and the drive substrate 150 are bonded in advance and the counter substrate 140 and the phosphor layer 120 are stacked in advance, following which the light-emitting device layer 110 and the phosphor layer 120 are bonded by the bonding structure 130. Accordingly, in the display apparatus 1 according to the present embodiment, the partition wall 121 and the phosphor layer 120 are formed on the counter substrate 140 which is flat and rigid. As a result, in the display apparatus 1 according to the present embodiment, the partition wall 121 that separates the phosphor layer 120 for each of the pixels is so provided as to have a higher uniformity in an in-plane direction of the counter substrate 140.

Incidentally, in a case where a display apparatus is formed by stacking the connection part 160, the light-emitting device layer 110, the bonding structure 130, the phosphor layer 120, and the counter substrate 140 in order from the drive substrate 150 side, a face, of the light-emitting device layer 110, on which the bonding structure 130 is to be provided is susceptible to distortion in the in-plane direction. This is because a solder 162 of the connection part 160 tends to involve a variation in the extent of melting and a variation tends to occur in a distance between the drive substrate 150 and the light-emitting device layer 110 accordingly. Therefore, in such a display apparatus, it is difficult to uniformize the height or the like of the partition wall 121 provided on the light-emitting device layer 110 in the in-plane direction of the phosphor layer 120, resulting in a variation in the luminance or the tone of each of the pixels in the in-plane direction.

Because the display apparatus 1 according to the present embodiment makes it possible to increase the uniformity of the height of the partition wall 121 in the in-plane direction of the phosphor layer 120, it is possible to suppress the variation in the luminance or the tone of each of the pixels in the in-plane direction.

It should be noted that materials structuring the first oxidation film 131, the bonding oxidation film 133, and the second oxidation film 132 may be selected such that a light extraction efficiency of the light from the light-emitting device layer 110 is optimized for the bonding structure 130. Specifically, in order to control a light path of the light emitted from the light-emitting device layer 110, refractive indices of materials structuring the first oxidation film 131, the bonding oxidation film 133, and the second oxidation film 132 may be controlled for the bonding structure 130. For example, the bonding structure 130 may be so provided that the refractive index of the bonding oxidation film 133 is higher than the refractive indices of the first oxidation film 131 and the second oxidation film 132.

The counter substrate 140 is a layer that protects the phosphor layer 120 from an external environment. The counter substrate 140 is provided on a face, of the phosphor layer 120, that is on an opposite side of the face provided with the bonding structure 130. The counter substrate 140 includes a transparent material that allows for transmission of light of a visible light band, for example, in order to cause the light emitted from the light-emitting device layer 110 to transmit therethrough. For example, the counter substrate 140 may include a transparent inorganic material such as borosilicate glass, quartz glass, or sapphire glass, or a transparent organic material such as acrylic resin.

In the display apparatus 1, the light emitted from the light-emitting device layer 110 is transmitted through the bonding structure 130, which is then converted into light having a desired color for each of the pixels by the phosphor layer 120, following which the converted light is transmitted through the counter substrate 140 to be visually recognized by the user. Accordingly, in the display apparatus 1, the face, of the counter substrate 140, that is on the opposite side of the face provided with the phosphor layer 120 serves as the image display face as described above.

In the display apparatus 1, the partition wall 121 and the phosphor layer 120 are formed on the counter substrate 140, following which the bonding structure 130 is used to bond the light-emitting device layer 110 and the phosphor layer 120. With this configuration, in the display apparatus 1, the phosphor layer 120 is automatically sealed by the counter substrate 140 after the bonding of the light-emitting device layer 110 and the phosphor layer 120. Accordingly, in the display apparatus 1, it is not necessary to form a structure that seals the phosphor layer 120 on the phosphor layer 120 after bonding the light-emitting device layer 110 and the phosphor layer 120, making it possible to reduce a damage on the phosphor layer 120 caused by a manufacturing process.

The drive substrate 150 includes a circuit that drives the light-emitting devices provided in the light-emitting device layer 110, and is provided via the connection part 160 on a face, of the light-emitting device layer 110, that is on an opposite side of the face that faces the phosphor layer 120. The drive substrate 150 includes a pixel circuit that individually drives the light-emitting devices provided in the light-emitting device layer 110 for each of the pixels, and a common circuit that scans each of the pixels in a vertical direction or a horizontal direction. The drive substrate 150 may be, for example, a semiconductor substrate such as Si (silicon) or a resin substrate such as PCB (PolyChlorinated Biphenyl).

The pixel circuit includes a plurality of MOSFETs, and is provided for each of the pixels. The pixel circuit is electrically coupled to a corresponding pixel of the light-emitting device layer 110 via the connection part 160, for example. The common circuit includes a vertical driving circuit and a horizontal driving circuit that sequentially scan respective vertical driving line and horizontal driving line that are orthogonal to each other, and is disposed on the outer periphery of the pixel circuit. Each of the pixels corresponds to each intersection of the vertical driving line and the horizontal driving line, and it is possible for the display apparatus 1 to drive each of the pixels by sequentially driving the vertical driving line and the horizontal driving line included in the common circuit.

The connection part 160 electrically couples the light-emitting device layer 110 and the drive substrate 150 by a so-called flip-chip connection. The connection part 160 may be, for example, a structure in which a plurality of bumps 161 provided on the drive substrate 150 side and a plurality of bumps (not illustrated) provided on the light-emitting device layer 110 side are bonded by a solder 162.

Specifically, the connection part 160 may be formed by, for example, the following process.

First, the solder 162 is placed on the bumps 161 provided on each of the pixel circuit and the common circuit of the drive substrate 150. Next, the light-emitting device layer 110 and the drive substrate 150 are caused to face each other such that the bumps provided on the light-emitting device layer 110 and the bumps 161 provided on the drive substrate 150 correspond to each other. Subsequently, the light-emitting device layer 110 and drive substrate 150 that face each other are brought into close contact with each other, and then heated to melt the solder 162. As a result, the bumps provided on the light-emitting device layer 110 and the bumps 161 provided on the drive substrate 150 are electrically coupled and physically bonded by the melted solder 162.

The display apparatus 1 according to the present embodiment is configured by bonding the light-emitting device layer 110 and the phosphor layer 120 by the bonding structure 130. With this configuration, it is possible for the display apparatus 1 to form the partition wall 121 and the phosphor layer 120 on the counter substrate 140 having a high flatness in the in-plane direction, making it possible to improve the uniformity in the in-plane direction of the height of the partition wall 121. Accordingly, it is possible for the display apparatus 1 to suppress the in-plane variation in the luminance or the tone of each of the pixels caused by the height variation of the partition wall 121.

In addition, it is possible for the display apparatus 1 to bond a stack of the light-emitting device layer 110 and the phosphor layer 120 at a room temperature, making it possible to prevent characteristics of the light converting substance included in the phosphor layer 120 from decreasing by heat.

### 2. METHOD OF MANUFACTURING DISPLAY APPARATUS

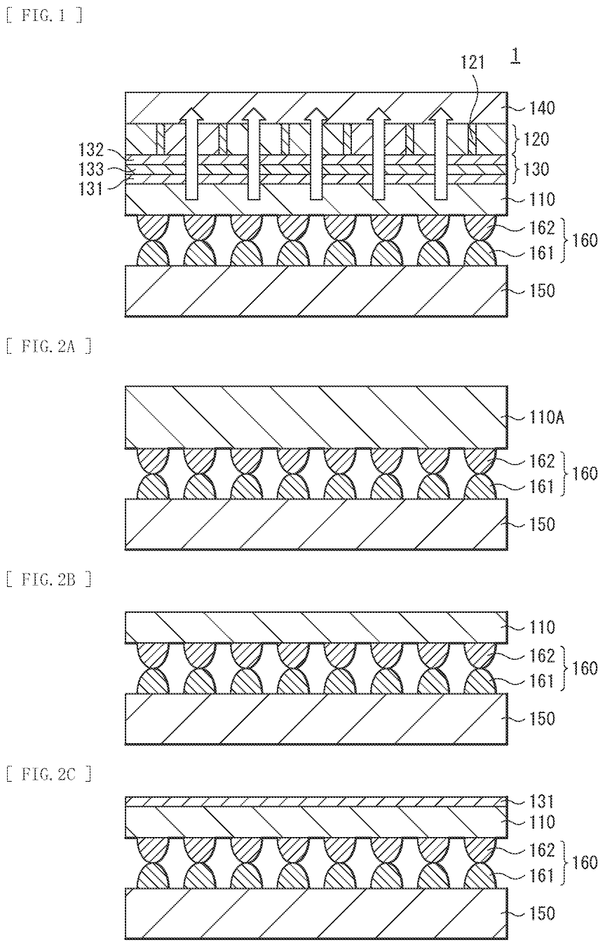

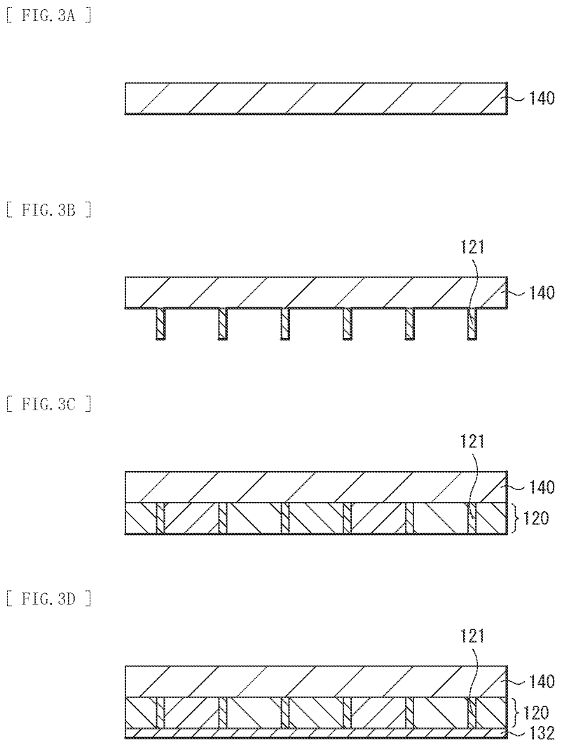

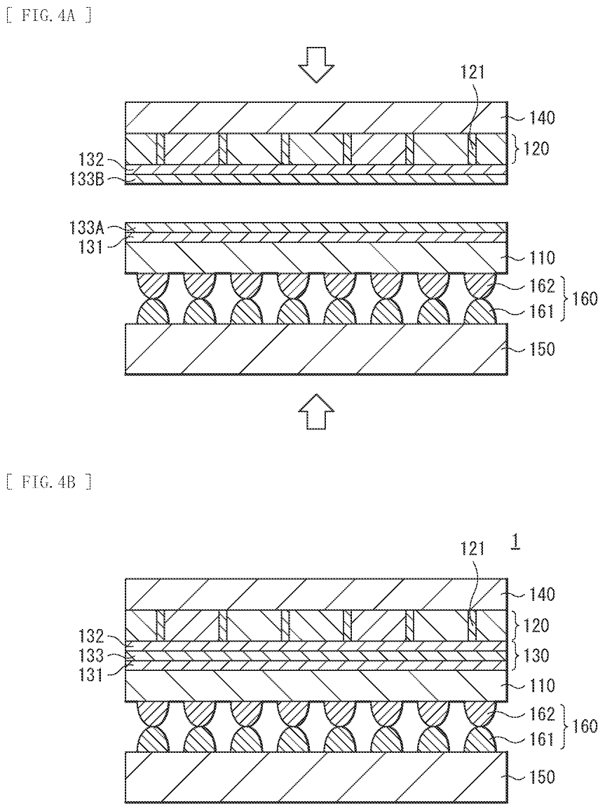

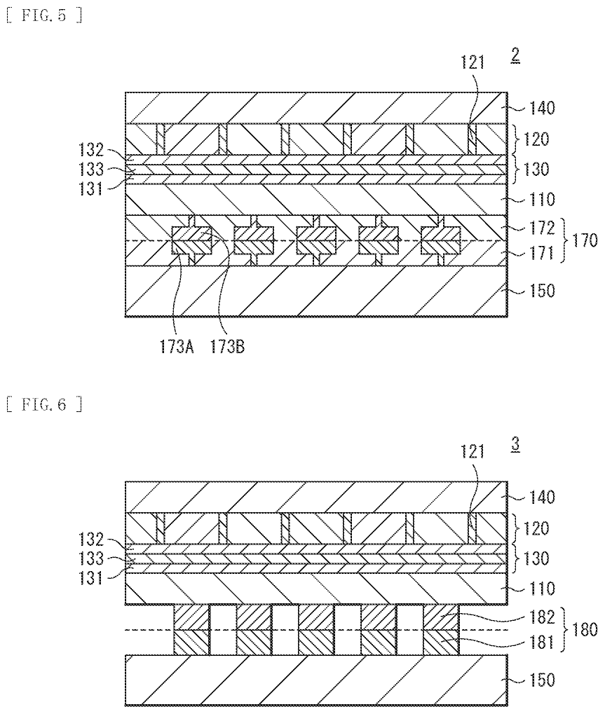

Next, referring to FIGS. 2A to 4B, a method of manufacturing the display apparatus 1 according to the present embodiment will be described. FIGS. 2A to 2C are each a vertical cross-sectional diagram illustrating a step of bonding the drive substrate 150 and the light-emitting device layer 110. FIGS. 3A to 3D are each a vertical cross-sectional diagram illustrating a step of stacking the counter substrate 140 and the phosphor layer 120. FIGS. 4A and 4B are each a vertical cross-sectional diagram illustrating a step of bonding the light-emitting device layer 110 and the phosphor layer 120.

First, referring to FIGS. 2A to 2C, a process of bonding the drive substrate 150 and the light-emitting device layer 110 will be described.

As illustrated in FIG. 2A, the light-emitting device layer 110A and the drive substrate 150 are bonded to each other using the bumps 161 and the solder 162. Specifically, first, the light-emitting device layer 110A in which a plurality of light-emitting diodes is formed on a semiconductor substrate is prepared. In addition, the drive substrate 150 is prepared that is formed with the pixel circuit that drives the light-emitting diodes provided in the light-emitting device layer 110A and with the common circuit that scans the driving of the light-emitting diodes in a vertical direction or a horizontal direction. Next, the light-emitting device layer 110A and the drive substrate 150 are caused to face to each other such that the bumps provided on each of the light-emitting device layer 110A and the drive substrate 150 face each other with the solder 162 being interposed therebetween. Subsequently, the solder 162 is melted by heating, thereby electrically coupling the light-emitting device layer 110A and the drive substrate 150 and physically bonding them to each other.

Subsequently, as illustrated in FIG. 2B, a semiconductor substrate included in the light-emitting device layer 110A is thinned by using a CMP (Chemical Mechanical Polish) method or the like. Specifically, the semiconductor substrate on which the light-emitting diodes are formed is thinned by polishing the light-emitting device layer 110A from a face that is on an opposite side of a bonding face with the drive substrate 150 by the CMP method or the like. As a result, in the thus-thinned light-emitting device layer 110, it is possible to extract light emitted from the light-emitting diodes from the face that is on the opposite side of the bonding face of the drive substrate 150.

Next, as illustrated in FIG. 2C, the first oxidation film 131 is formed on the face, of the light-emitting device layer 110, that is on the opposite side of the face that faces the drive substrate 150. For example, the first oxidation film 131 may be formed by SiO₂ (silicon dioxide).

Next, referring to FIGS. 3A to 3D, a process of stacking the counter substrate 140 and the phosphor layer 120 will be described.

As illustrated in FIG. 3A, the transparent counter substrate 140 is prepared. The counter substrate 140 may be, for example, a borosilicate glass substrate, or a quartz substrate.

Subsequently, as illustrated in FIG. 3B, the partition wall 121 is formed on one surface of the counter substrate 140 in such a manner as to correspond to a region between each of the pixels. The partition wall 121 may be formed by, for example, SiN (silicon nitride) using lithography and etching. At this time, the partition wall 121 is formed using the lithography and the etching on the flat counter substrate 140, allowing the partition wall 121 to be formed such that the height thereof becomes more uniform in the in-plane direction of the counter substrate 140.

Next, as illustrated in FIG. 3C, the phosphor layer 120 is formed by introducing the light converting substance for each of the pixels into regions defined by the partition wall 121. As the light converting substance, for example, it is possible to use an organic fluorescence material or the like that emits a fluorescence corresponding to a color of the pixel. The organic fluorescence material may be introduced using, for example, a vapor deposition method or a print method in the regions defined by the partition wall 121.

Thereafter, as illustrated in FIG. 3D, the second oxidation film 132 is formed on a face, of the phosphor layer 120, that is on the opposite side of the face that faces the counter substrate 140. For example, the second oxidation film 132 may be formed by SiO₂ (silicon dioxide).

Further, referring to FIGS. 4A and 4B, a process of bonding the light-emitting device layer 110 and the phosphor layer 120 will be described.

As illustrated in FIG. 4A, the phosphor layer 120 and the light-emitting device layer 110 are caused to face to each other, a precursor film 133A is formed on the first oxidation film 131 on the phosphor layer 120 side, and a precursor film 133B is formed on the second oxidation film 132 on the light-emitting device layer 110 side.

Specifically, a stack of the counter substrate 140 and the phosphor layer 120 and a bonded body of the drive substrate 150 and the light-emitting device layer 110 are introduced into the same vacuum chamber. Next, the precursor film 133A is formed on the first oxidation film 131 and the precursor film 133B is formed on the second oxidation film 132 under an ultra-high vacuum. The precursor films 133A and 133B are unoxidized metal films which eventually become the bonding oxidation film 133 at a later stage, and may be formed by, for example, forming an extreme thin film (e.g., about several nanometers) of Al (aluminum) or Ti (titanium).

Subsequently, as illustrated in FIG. 4B, the atomic diffusion bonding is performed by bringing the precursor film 133A and the precursor film 133B into contact with each other under vacuum. This makes it possible to bond to each other the precursor film 133A on the phosphor layer 120 side and the precursor film 133B on the light-emitting device layer 110 side. Further, after the bonding, heating of about 100° C. is performed to diffuse the oxygen atoms included in the first oxidation film 131 and the second oxidation film 132 into the precursor films 133A and 133B so as to oxidize the precursor films 133A and 133B. This makes it possible to form the bonding oxidation film 133 configured by transparent Al₂O₃ (aluminum oxide) or TiO₂ (titanium oxide).

Through the above steps, it is possible to manufacture the display apparatus 1 according to the present embodiment.

In the method of manufacturing the display apparatus 1 according to the present embodiment, the partition wall 121 is formed on the counter substrate 140 having the high flatness in the in-plane direction, making it possible to improve the uniformity in the in-plane direction of the height of the partition wall 121. Accordingly, it is possible for the display apparatus 1 to suppress the in-plane variation of the luminance or the tone of each of the pixels caused by the height variation of the partition wall 121.

Further, in the method of manufacturing the display apparatus 1 according to the present embodiment, a temperature to be applied to the phosphor layer 120 is at most about 100° C., making it possible to suppress the light converting substance included in the phosphor layer 120 from decreasing the characteristics by heat. Further, in the method of manufacturing the display apparatus 1 according to the present embodiment, it is possible to seal the phosphor layer 120 by the counter substrate 140 without damaging the phosphor layer 120.

### 3. MODIFICATION EXAMPLES

Next, referring to FIGS. 5 and 6, modification examples of the display apparatus 1 according to the present embodiment will be described. The modification examples of the display apparatus 1 according to the present embodiment are those in which configurations other than the bumps 161 and the solder 162 are applied to the connection part 160 that bonds the drive substrate 150 and the light-emitting device layer 110. FIG. 5 is a vertical cross-sectional diagram illustrating a configuration of a display apparatus 2 according to a first modification example, and FIG. 6 is a vertical cross-sectional diagram illustrating a configuration of a display apparatus 3 according to a second modification example.

It should be noted that the display apparatus 1 according to the present embodiment is substantially similar to the display apparatus 2 according to the first modification example and the display apparatus 3 according to the second modification example for the configurations other than the connection part 160 related to the bonding of the drive substrate 150 and the light-emitting device layer 110. Accordingly, the description of these configurations will be omitted here.

### First Modification Example

As illustrated in FIG. 5, in the display apparatus 2 according to the first modification example, a connection part 170 that bonds the drive substrate 150 and the light-emitting device layer 110 may be configured by a pad electrode 173A exposed on a surface of an insulation layer 171 and a pad electrode 173B exposed on a surface of an insulation layer 172.

Specifically, the drive substrate 150 is provided with the insulation layer 171 formed by, for example, SiO₂ (silicon dioxide), SiN (silicon nitride), or the like, and the insulation layer 171 is provided with the pad electrode 173A that is formed by, for example, Cu (copper) or the like and so provided as to expose on the surface of the insulation layer 171. On the other hand, similarly, the light-emitting device layer 110 is provided with the insulation layer 172 formed by, for example, SiO₂ (silicon dioxide), SiN (silicon nitride), or the like, and the insulation layer 172 is provided with the pad electrode 173B that is formed by, for example, Cu (copper) or the like and so provided as to expose on the surface of the insulation layer 172.

Here, the drive substrate 150 and the light-emitting device layer 110 are bonded by causing the insulation layer 171 and the insulation layer 172 to face each other such that the pad electrode 173A and the pad electrode 173B come into contact with each other and performing a heating process. Accordingly, with such a connection part 170, the drive substrate 150 and the light-emitting device layer 110 are electrically coupled by the pad electrode 173A and the pad electrode 173B, and are physically bonded by the insulation layer 171 and the insulation layer 172. A bonding structure based on the pad electrode 173A and the pad electrode 173B exposed on the surfaces of the respective insulation layer 171 and insulation layer 172 is also referred to as a Cu-Cu connection structure.

With the display apparatus 2 according to the first modification example, it is possible to electrically couple the drive substrate 150 and the light-emitting device layer 110 by the Cu—Cu connection structure described above as well.

### Second Modification Example

As illustrated in FIG. 6, in the display apparatus 3 according to the second modification example, a connection part 180 that bonds the drive substrate 150 and the light-emitting device layer 110 may be configured by a pillar bump 181 and a pillar bump 182 provided on each of the drive substrate 150 and the light-emitting device layer 110.

Specifically, the drive substrate 150 is provided with the columnar pillar bump 181 formed by Cu (copper) or the like. An upper surface of the pillar bump 181 is provided with a hemispherical solder (not illustrated) for bonding with the pillar bump 182 provided on the light-emitting device layer 110 side. On the other hand, similarly, the light-emitting device layer 110 is provided with the columnar pillar bump 182 formed by Cu (copper) or the like.

Here, the drive substrate 150 and the light-emitting device layer 110 are bonded by bringing the pillar bump 181 and the pillar bump 182 into contact with each other, followed by performing a heating process, and melting a solder sandwiched between the pillar bump 181 and the pillar bump 182. With such a connection part 180, the drive substrate 150 and the light-emitting device layer 110 are electrically and physically coupled by the solder sandwiched between the pillar bump 181 and the pillar bump 182.

With the display apparatus 3 according to the second modification example, it is possible to electrically couple the drive substrate 150 and the light-emitting device layer 110 by the pillar bump connection structure described above as well.

### 4. APPLICATION EXAMPLE

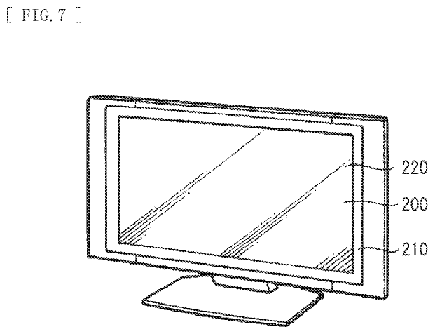

It is possible to apply the display apparatus 1 according to the present embodiment to various electronic devices that display an image signal inputted from outside or an image signal generated internally. For example, it is possible to apply the display apparatus 1 according to the present embodiment to a television apparatus, a digital camera, a notebook personal computer, a mobile phone, a smartphone, or the like. Referring to FIG. 7, an example of an application example of the display apparatus 1 according to the present embodiment is illustrated. FIG. 7 is a schematic diagram illustrating an appearance of a television apparatus to which the display apparatus 1 according to the present embodiment is applied.

As illustrated in FIG. 7, a television apparatus 200 has an image displaying part 210 including a front panel 220 and a filter glass 230, for example. The display apparatus 1 according to the present embodiment may be applied to such an image displaying part 210.

A technique according to the present disclosure has been described above with reference to the embodiment and the modification examples. However, the technique according to the present disclosure is not limited to the above-described embodiment and the like, and various modifications can be made.

For example, it is possible to apply the display apparatus 1 according to the present embodiment to various displays. Specifically, it is also possible to apply the display apparatus 1 according to the present embodiment to a liquid crystal display, a plasma panel display, an OLED display, a micro-LED display, or the like.

Further, not all of the configurations and operations described in the respective embodiments are essential to the configuration and the operation of the present disclosure. For example, among the elements in the respective embodiments, elements not recited in an independent claim based on the most generic concept of the present disclosure are to be understood as optional components.

The terms used throughout this specification and the appended claims should be construed as “non-limiting” terms. For example, the terms “including” or “included” should be construed as “not being limited to an embodiment in which it is described as including”. The term “has” should be construed as “not being limited to an embodiment in which it is described as having”.

The terms used in this specification are used merely for convenience of description and include terms that are not used for the purpose of limiting a configuration and an operation. For example, terms such as “right,” “left,” “up,” and “down” merely indicate a direction in the drawing being referenced. In addition, the terms “inner” and “outer” merely indicate directions toward the center of an element of interest and away from the center of the element of interest, respectively. This applies similarly to terms similar to these terms and terms having the similar meanings.

It should be noted that the technique according to the present disclosure may have the following configurations. According to the technique of the present disclosure having the following configurations, it is possible to bond the light-emitting device layer and the phosphor layer by sandwiching the bonding structure in which the first oxidation film, the bonding oxidation film, and the second oxidation film are stacked in order from the light-emitting device layer side between the light-emitting device layer and the phosphor layer. Thus, it is possible for the display apparatus to further increase a uniformity of a height of the partition wall that separates the phosphor layer for each of the pixels, and therefore to further increase a luminance or a tone of each of the pixels. An effect to be exerted by the technique according to the present disclosure is not necessarily limited to the effect described herein, and may be any of the effects described in the present disclosure.

(1)

A display apparatus including:

a light-emitting device layer provided to extend over a plurality of pixels arranged two-dimensionally;

a phosphor layer separated by a partition wall for each of the pixels; and a bonding structure sandwiched between the light-emitting device layer and the phosphor layer, and in which a first oxidation film, a bonding oxidation film, and a second oxidation film are stacked in order from the light-emitting device layer side.

(2)

The display apparatus according to (1), in which the bonding oxidation film is configured by an oxide having a light transmitting property.

(3)

The display apparatus according to (2), in which the oxide having the light transmitting property is an oxide of Sc, Y, Ti, V, Cr, Fe, Co, Ni, Pd, Cu, Ag, Sg, Mg, Sr, Zn, Zr, Al, or Si, or an oxide of an alloy thereof.

(4)

The display apparatus according to (3), in which the oxide having the light transmitting property is the oxide of Ti or Al.

(5)

The display apparatus according to any one of (1) to (4), in which a refractive index of the bonding oxidation film is higher than a refractive index of the first oxidation film and a refractive index of the second oxidation film.

(6)

The display apparatus according to any one of (1) to (5), in which the first oxidation film and the second oxidation film are configured by an oxide of same element as each other.

(7)

The display apparatus according to (6), in which the first oxidation film and the second oxidation film are configured by a silicon oxide.

(8)

The display apparatus according to any one of (1) to (7), in which a transparent substrate that seals the phosphor layer is further provided on a face, of the phosphor layer, that is on an opposite side of a face provided with the bonding structure.

(9)

The display apparatus according to any one of (1) to (8), in which the phosphor layer includes two or more kinds of light converting substances, and the phosphor layer includes any of the two or more kinds of light converting substances for each of the pixels.

(10)

The display apparatus according to any one of (1) to (9), in which the partition wall is configured by a material having at least any one of a light shielding property or an insulating property.

(11)

The display apparatus according to any one of (1) to (10), in which

the light-emitting device layer is provided with light-emitting diodes for the respective pixels, and

the light-emitting diodes provided for the respective pixels are each driven by a drive substrate electrically coupled to the light-emitting device layer.

(12)

The display apparatus according to (11), in which the light-emitting device layer and the drive substrate are electrically coupled by a solder bump.

(13)

The display apparatus according to (11), in which the light-emitting device layer and the drive substrate are electrically coupled by attaching, to each other, faces on each of which a pad electrode is exposed.

(14)

The display apparatus according to (11), in which the light-emitting device layer and the drive substrate are electrically coupled by a cylindrical pillar bump.

The present application claims the benefit of Japanese Priority Patent Application JP2020-019371 filed with the Japan Patent Office on Feb. 7, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A display apparatus comprising:
a light-emitting device layer provided to extend over a plurality of pixels arranged two-dimensionally;
a phosphor layer separated by a partition wall for each of the pixels; and
a bonding structure sandwiched between the light-emitting device layer and the phosphor layer, and in which a first oxidation film, a bonding oxidation film, and a second oxidation film are stacked in order from the light-emitting device layer side.

2. The display apparatus according to claim 1, wherein the bonding oxidation film is configured by an oxide having a light transmitting property.

3. The display apparatus according to claim 2, wherein the oxide having the light transmitting property is an oxide of Sc, Y, Ti, V, Cr, Fe, Co, Ni, Pd, Cu, Ag, Sg, Mg, Sr, Zn, Zr, Al, or Si, or an oxide of an alloy thereof.

4. The display apparatus according to claim 3, wherein the oxide having the light transmitting property is the oxide of Ti or Al.

5. The display apparatus according to claim 1, wherein a refractive index of the bonding oxidation film is higher than a refractive index of the first oxidation film and a refractive index of the second oxidation film.

6. The display apparatus according to claim 1, wherein the first oxidation film and the second oxidation film are configured by an oxide of same element as each other.

7. The display apparatus according to claim 6, wherein the first oxidation film and the second oxidation film are configured by a silicon oxide.

8. The display apparatus according to claim 1, wherein a transparent substrate that seals the phosphor layer is further provided on a face, of the phosphor layer, that is on an opposite side of a face provided with the bonding structure.

9. The display apparatus according to claim 1, wherein the phosphor layer includes two or more kinds of light converting substances, and the phosphor layer includes any of the two or more kinds of light converting substances for each of the pixels.

10. The display apparatus according to claim 1, wherein the partition wall is configured by a material having at least any one of a light shielding property or an insulating property.

11. The display apparatus according to claim 1, wherein
the light-emitting device layer is provided with light-emitting diodes for the respective pixels, and
the light-emitting diodes provided for the respective pixels are each driven by a drive substrate electrically coupled to the light-emitting device layer.

12. The display apparatus according to claim 11, wherein the light-emitting device layer and the drive substrate are electrically coupled by a solder bump.

13. The display apparatus according to claim 11, wherein the light-emitting device layer and the drive substrate are electrically coupled by attaching, to each other, faces on each of which a pad electrode is exposed.

14. The display apparatus according to claim 11, wherein the light-emitting device layer and the drive substrate are electrically coupled by a cylindrical pillar bump.
